(19) United States
(12) Patent Application Publication
(10) Pub. No.: US 2025/0151293 A1
(43) Pub. Date: May 8, 2025

(54) HIGH BANDWIDTH MEMORY

(71) Applicant: Samsung Electronics Co., Ltd., Suwon-si (KR)

(72) Inventors: Jeehyun JUNG, Suwon-si (KR); Hansung RYU, Suwon-si (KR); Jongbeom PARK, Suwon-si (KR)

(73) Assignee: Samsung Electronics Co., Ltd., Suwon-si (KR)

(21) Appl. No.: 18/738,574

(22) Filed: Jun. 10, 2024

(30) Foreign Application Priority Data
Nov. 8, 2023 (KR) 10-2023-0153673

(51) Int. Cl. H10B 80/00; H01L 23/00; H01L 25/065

(52) U.S. Cl. CPC H10B 80/00; H01L 24/08; H01L 25/0657; H01L 2224/08145; H01L 2225/06513; H01L 2225/06541; H01L 2225/06555; H01L 2225/06586; H01L 2924/1436

(57) ABSTRACT

A high bandwidth memory includes a base die and a memory stack on the base die. The memory stack includes a plurality of memory dies. The memory stack includes a first memory die closest to the base die among the plurality of memory dies and having a first width in a horizontal direction, and a second memory die on the first memory die and having a second width in the horizontal direction, the first width is smaller than the second width.

### CROSS-REFERENCE TO RELATED APPLICATION

This application claims priority to and the benefit of Korean Patent Application No. 10-2023-0153673 filed in the Korean Intellectual Property Office on Nov. 8, 2023, the entire contents of which are incorporated herein by reference.

### BACKGROUND

### (a) Field

The present inventive concepts relate to high bandwidth memories.

### (b) Description of the Related Art

The semiconductor industry is pursuing work to down-size, lighten, and thin (e.g., miniaturize) the semiconductor packages mounted in electronic devices, while simultaneously pursuing higher operating speed, multifunction capability, and large capacity, in response to the demand for down-sizing and lightening of electronic devices. Therefore, the need for a packaging technology capable of storing more data and transmitting data at a higher speed is increasing, and one such packaging technology is high bandwidth memory (HBM), which can achieve high levels of bandwidth by stacking more DRAMs on the same area of substrate.

HBM is manufactured by stacking a plurality of DRAMs on a buffer die. As the number of DRAMs stacked on a buffer die increases, it is possible to implement high-performance HBM. However, if the height of the stacked DRAMs increases rapidly compared to the area of the upper surface of the buffer die in contact with the DRAM, excessive structural stress concentration may occur at the corner of the end of the interface formed by the contact between the buffer die and the DRAM.

### SUMMARY

In order to relieve stress concentration at the corner, some example embodiments of the inventive concepts design the corner to have a fillet or round shape. Some example embodiments of the inventive concepts apply machining to form the shape of a fillet or round at the corner, but it is difficult to implement in the process. In addition, due to the addition of machining steps, turn around time (TAT) may increase and the yield may deteriorate.

Some example embodiments of the inventive concepts provide a new HBM technology capable of solving the issues of the conventional HBM technology.

In some example embodiments of the inventive concepts, the size of the memory dies placed adjacent to the buffer die among the memory dies stacked on the buffer die may be adjusted, so that the corner at the end of the interface formed by the contact between the buffer die and the memory stack has a fillet or round shape.

A high bandwidth memory according to some example embodiments may include a base die; and a memory stack on the base die, wherein the memory stack includes a plurality of memory dies. The memory stack may include a first memory die closest to the base die among the plurality of memory dies and having a first width in a horizontal direction, the horizontal direction extending parallel to an in-plane direction of the base die; and a second memory die on the first memory die and having a second width in the horizontal direction, wherein the first width is smaller than the second width.

A high bandwidth memory according to some example embodiments may include a base die; and a memory stack on the base die, wherein the memory stack includes a first sub-memory stack and a second sub-memory stack, the first sub-memory stack includes a plurality of first memory dies, and the second sub-memory stack each includes a plurality of second memory dies, wherein the first sub-memory stack may have a profile in which a horizontal width in a horizontal direction of each memory die of the plurality of first memory dies increases from a lower first memory die of the plurality of first memory dies to an upper first memory die of the plurality of first memory dies, the lower first memory die closest to the base die among the plurality of first memory dies, the horizontal direction extending parallel to an in-plane direction of the base die, and wherein the second sub-memory stack may have a profile in which a horizontal width of each memory die of the plurality of second memory dies decreases from a lower second memory die of the plurality of second memory dies to an upper second memory die of the plurality of second memory dies, the lower second memory die closest to the base die among the plurality of second memory dies.

A high bandwidth memory according to some example embodiments may include a base die; a memory stack on the base die, including a plurality of memory dies stacked; and a plurality of interconnection structures; and a molding material molding the memory stack on the base die, wherein the plurality of memory dies may include: a first memory die closest to the base die among the plurality of memory dies and having a first width in horizontal direction, the horizontal direction extending parallel to an in-plane direction of the base die; and a second memory die on the first memory die and having a second width in the horizontal direction greater than the first width, the plurality of interconnection structures may include a first interconnection structure connecting the base die and the first memory die; and a second interconnection structure connecting the first memory die and the second memory die.

The size of the memory dies placed adjacent to the buffer die among the memory dies stacked on the buffer die may be adjusted, so that the corner at the end of the interface formed by the contact between the buffer die and the memory stack has a fillet or round shape. Thus, it is possible to alleviate the stress concentrated at the corner.

In addition, in order to relieve the stress concentrated at the corner, it is possible to improve warpage characteristics of the high bandwidth memory (HBM) by adjusting the sizes of the memory dies disposed above the memory dies that are disposed adjacent to the buffer die and have adjustable sizes.

### BRIEF DESCRIPTION OF THE DRAWINGS

FIG. 1 is a cross-sectional view of a conventional high bandwidth memory.

FIG. 2 is a cross-sectional view of a high bandwidth memory according to some example embodiments.

FIG. 3 is a cross-sectional view of a high bandwidth memory according to some example embodiments.

FIG. 4 is a cross-sectional view of a high bandwidth memory according to some example embodiments.

FIG. 5 is a cross-sectional view of a high bandwidth memory according to some example embodiments.

FIG. 6 is a cross-sectional view of a high bandwidth memory according to some example embodiments.

FIG. 7 is a cross-sectional view of a high bandwidth memory according to some example embodiments.

### DETAILED DESCRIPTION

Hereinafter, the present inventive concepts will be described in detail hereinafter with reference to the accompanying drawings, in which embodiments of the present inventive concepts are shown. As those skilled in the art would realize, the described embodiments may be modified in various different ways, all without departing from the spirit or scope of the present inventive concepts.

The drawings and description are to be regarded as illustrative in nature and not restrictive. Like reference numerals designate like elements throughout the specification.

Size and thickness of each constituent element in the drawings are arbitrarily illustrated for better understanding and ease of description, the following embodiments are not limited thereto.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

Hereinafter, a high bandwidth memory (HBM) according to some example embodiments will be described with reference to the drawings.

HBM is a high-performance three-dimensional (3D) stacked dynamic random-access memory (DRAM). HBM may be manufactured using through silicon via (TSV) technique, which is vertically stacking memory dies including DRAM circuits to form a single memory stack, forming thousands of tiny holes that penetrate vertically through the stacked memory dies, and filling the holes with conductive material to electrically connect the memory dies.

HBM has multiple memory channels through a memory stack in which memory dies are vertically stacked, enabling shorter latency and higher bandwidth simultaneously compared to conventional DRAM products, and the total area occupied by individual DRAMs on the printed circuit board (PCB) can be reduced, which is advantageous for high bandwidth compared to the area and has the advantage of reducing power consumption.

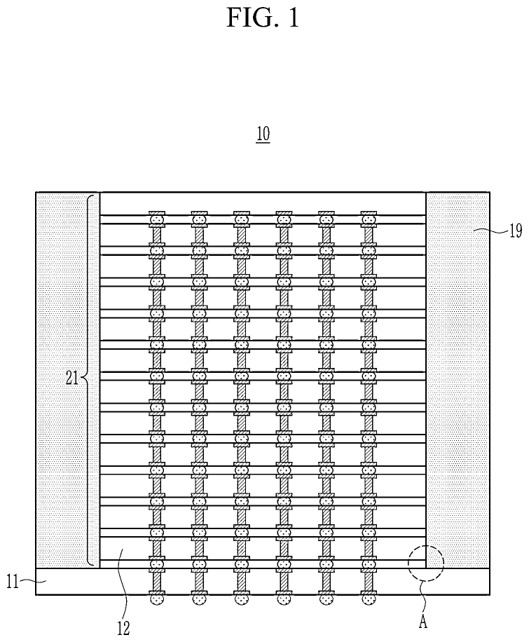

FIG. 1 is a cross-sectional view of a conventional high bandwidth memory (HBM) 10.

Referring to FIG. 1, a high bandwidth memory (HBM) 10 includes a buffer die 11, memory dies 12, and molding material 19. The HBM 10 includes a 12H-memory stack. The 12H-memory stack refers to a memory stack 21 in which 12 memory dies 12 are stacked.

In this way, the HBM 10 is formed by placing the memory stack 21 manufactured by stacking a plurality of memory dies 12 on the buffer die 11. Accordingly, as the number (quantity) of the memory dies 12 included in the memory stack 21 increases, it is possible to implement a high-performance HBM 10. However, if the height of the memory stack 21 increases compared to the area of the buffer die 11 by increasing the number of the memory dies 12 included in the memory stack 21, excessive structural stress concentration may occur at the corner A at the end of the interface formed by the contact of the buffer die 11 and the memory die 12 at the bottom (e.g., adjacent to the buffer die 11, closest to the buffer die 11 among the memory dies 12 included in the memory stack 21, etc.), and this may cause cracks (e.g., cracks in the HBM 10) at the corner A.

Further, the HBM 10 includes the molding material 19 that molds the memory stack 21 on the buffer die 11. The molding material 19 has the function of protecting the memory stack 21 electrically and chemically. However, since the thermal characteristics of the molding material 19 and the thermal characteristics of the memory stack 21 are different from each other, warpage may occur in the HBM 10 due to the difference in thermal characteristics.

Conventional high bandwidth memory HBM 10 is manufactured by stacking the memory dies 12 with fixed sizes in the horizontal direction (e.g., stacking memory dies 12 that each have a fixed size in the horizontal direction on the buffer die 11 in the vertical direction). In addition, in order to implement high-performance HBM 10, technology development is proceeding in a direction that reduces the vertical height of each memory die 12 and increases the number (quantity) of the memory dies 12 included in the memory stack 21. Therefore, it is not easy to change the vertical size of the memory die 12. Therefore, considering these points, it is difficult to solve the warpage issue with the conventional HBM 10.

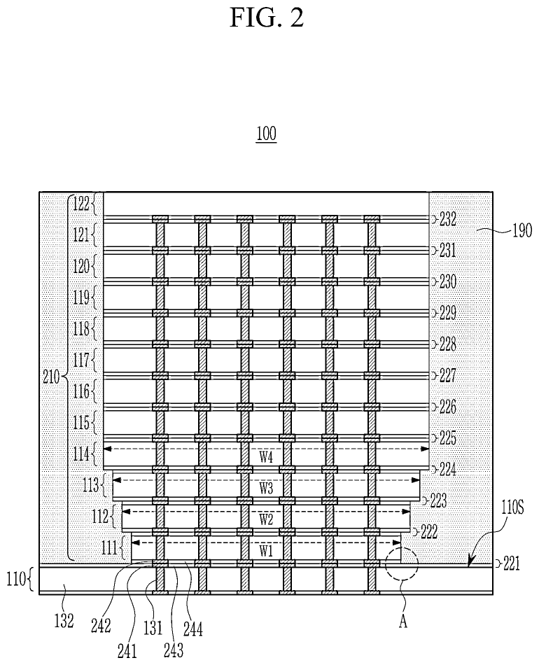

FIG. 2 is a cross-sectional view of the HBM 100 according to some example embodiments.

Referring to FIG. 2, a high bandwidth memory (HBM) 100 includes a buffer die 110, a 12H-memory stack 210 including a 1H-memory die 111 to a 12H-memory die 122, and a molding material 190. The 12H-memory stack 210 refers to a memory stack in which 12 memory dies are stacked. The memory dies arranged from the bottom to the top of the 12H-memory stack 210 are sequentially defined as the 1H-memory die 111 to the 12H-memory die 122.

The buffer die 110, also referred to herein as a barrier die, a base die, or the like, is disposed at the bottom of the HBM 100 and is disposed between the 12H-memory stack 210 and an external device (not shown). When data is exchanged between devices having different data processing speeds, processing units, and usage times, data loss may occur due to differences in data processing speeds, processing units, and usage times between devices. In order to reduce, minimize, or prevent this loss, the buffer die 110 may be disposed between the 12H-memory stack 210 and an external device (not shown), and information when data is exchanged between the 12H-memory stack 210 and an external device (not shown) may be temporarily stored in the buffer die 110. When transmitting data to or receiving data from the 12H-memory stack 210, the buffer die 110 sequences the data and then passes the data through sequentially. The buffer die 110 includes a channel (not shown), through silicon vias 131, and a die base 132. In some example embodiments, the buffer die 110 as described herein may be a base die. In some example embodiments, the buffer die 110 as described herein may be included in a base die.

The 12H-memory stack 210 is disposed on the buffer die 110. The 12H-memory stack 210 includes the 1H-memory die 111 to the 12H-memory die 122. In some example embodiments, the 12H-memory stack 210 may be coupled to the buffer die 110 by hybrid bonding. In some example embodiments, the 1H-memory die 111 to the 12H-memory die 122 of the 12H-memory stack 210 may be coupled to each other by hybrid bonding.

The hybrid bonding may be performed using a first interconnection structure 221 to a twelfth interconnection structure 232 between the buffer die 110 and the 12H-memory stack 210, or between the 1H-memory die 111 to the 12H-memory die 122 of the 12H-memory stack 210. Hybrid bonding is to bond two devices by fusing the same materials of the two devices using the bonding properties of the same material. Here, hybrid means that two different types of bonding are made, for example, bonding two devices with a first type of metal-metal bonding and a second type of non-metal-non-metal bonding. According to hybrid bonding, I/O with a fine pitch may be formed.

Each of the first to twelfth interconnection structures 221 to 232 includes first bonding pads 241, second bonding pads 242, a first silicon insulating layer 243, and a second silicon insulating layer 244. The first bonding pads 241 are disposed on the upper surface of the buffer die 110 or on the upper surface of each of the 1H-memory die 111 to the 11H-memory die 121. The second bonding pads 242 are disposed on the lower surfaces of each of the first to twelfth interconnection structures 221 to 232. The first silicon insulating layer 243 is disposed on the upper surface of the buffer die 110, or on the upper surface of each of the 1H-memory die 111 to the 11H-memory die 121. The second silicon insulating layer 244 is disposed on the lower surface of each of the 1H-memory die 111 to the 12H-memory die 122.

The first bonding pad 241 is directly bonded to the second bonding pad 242 by metal-metal hybrid bonding. A metal bond is formed at an interface between the first bonding pad 241 and the second bonding pad 242 by metal-metal hybrid bonding. In some example embodiments, the first bonding pad 241 and the second bonding pad 242 may include copper. In some example embodiments, the first bonding pad 241 and the second bonding pad 242 may be made of a metallic material capable of applying hybrid bonding.

Since the first bonding pad 241 and the second bonding pad 242 are made of the same material, the interface between the first bonding pad 241 and the second bonding pad 242 may disappear after hybrid bonding. The buffer die 110, the 12H-memory stack 210, and the 1H-memory die 111 to the 12H-memory die 122 are electrically connected to each other through the first bonding pad 241 and the second bonding pad 242.

The first silicon insulating layer 243 is directly bonded to the second silicon insulating layer 244 by non-metal-non-metal hybrid bonding. A covalent bonding is formed at the interface between the first silicon insulating layer 243 and the second silicon insulating layer 244 by non-metal-non-metal hybrid bonding. In some example embodiments, the first silicon insulating layer 243 and the second silicon insulating layer 244 may include silicon oxide or TEOS forming oxide. In some example embodiments, the first silicon insulating layer 243 and the second silicon insulating layer 244 may include SiO₂. In some example embodiments, the first silicon insulating layer 243 and the second silicon insulating layer 244 may be silicon nitride, silicon oxynitride, or other suitable dielectric material. In some example embodiments, the first silicon insulating layer 243 and the second silicon insulating layer 244 may include SiN or SiCN.

Since the first silicon insulating layer 243 and the second silicon insulating layer 244 are made of the same material, an interface between the first silicon insulating layer 243 and the second silicon insulating layer 244 may disappear after hybrid bonding.

The 1H-memory die 111 to the 11H-memory die 121 each include memory channels (not shown), through silicon vias 131, and the die base 132. The 12H-memory die 122 includes memory channels (not shown) and the die base 132. In some example embodiments, the 1H-memory die 111 to the 12H-memory die 122 may each be DRAM. In some example embodiments, the HBM 100 including fewer or greater numbers of memory dies are included within the scope of the present inventive concepts.

For electrical coupling between the buffer die 110 and the 1H-memory die 111 to the 12H-memory die 122, the buffer die 110 and the 1H-memory die 111 to the 11H-memory die 121 may include through silicon vias 131. The 12H-memory die 122 located at the top may not include through silicon vias 131. The through silicon vias 131 may be formed by drilling thousands of fine holes vertically penetrating each die, filling the holes with a conductive material, and connecting them to electrodes.

In some example embodiments, the hole of the through silicon via 131 may be formed by deep etching. In some example embodiments, the hole of the through silicon via 131 may be formed by a laser. In some example embodiments, the hole of the through silicon via 131 may be filled with a conductive material by electrolytic plating. In some example embodiments, the through silicon via 131 may include at least one of tungsten, aluminum, copper, or alloys thereof. In addition, a barrier layer (not shown) may be formed between the insulating material of the buffer die 110 and the through silicon via 131, and between the insulating material of the 1H-memory die 111 to the 11H-memory die 121 and the through silicon via 131. In some example embodiments, the barrier layer (not shown) may include at least one of titanium, tantalum, titanium nitride, tantalum nitride, or alloys thereof.

The 12H-memory stack 210 has a profile in which the horizontal width (e.g., a width in a horizontal direction extending parallel to the in-plane direction of the buffer die 110 and/or parallel to the upper surface 110S of the buffer die 110) of each memory die increases from the 1H-memory die 111 to a 4H-memory die 114, and the horizontal width of the 4H-memory die 114 to the 12H-memory die 122 is constant.

In some example embodiments, the 1H-memory die 111 to the 4H-memory die 114 of the 12H-memory stack 210 may have a stepped side profile. Thus, by adjusting the horizontal width of the 1H-memory die 111 to the 4H-memory die 114 (e.g., a horizontal width in a horizontal direction that extends parallel to an in-plane direction of the buffer die 110, for example a horizontal direction that extends parallel to an upper surface 110S of the buffer die 110), the corners at the ends of the interface formed by the buffer die 110 and the 12H-memory stack 210 may have a fillet or round shape (e.g., a fillet or round shape in a horizontal plane extending parallel to an in-plane direction of the buffer die 110, for example a horizontal plane that extends parallel to an upper surface 110S of the buffer die 110) without any additional machining.

Thus, it is possible to alleviate the stress concentrated at the corner. Restated, the HBM 100 may be configured to have reduced stress concentration at the corner A at the end of the interface formed by the contact of the buffer die 110 and memory stack 210 at the bottom memory die thereof (e.g., adjacent to the buffer die 110, closest to the buffer die 110 among the 1H-memory die 111 to the 12H-memory die 122 included in the memory stack 210, etc.) based on the 1H-memory die 111 that is closest to the buffer die 110 among the memory dies of the 12H-memory stack 210 having a horizontal width that is smaller than one or more (or all) of the remaining memory dies of the 12H-memory stack 210 on the 1H-memory die 111 (e.g., the 2H-memory die 112 to the 12H-memory die 122).

The 1H-memory die 111 has a first width W1 in the horizontal direction (e.g., the horizontal direction extending parallel to an in-plane direction of the buffer die 110, parallel to an upper surface 110S of the buffer die 110, or the like). Herein, the terms “width” and “horizontal width” may be used interchangeably and will be understood to refer to a width in a horizontal direction that is parallel to an in-plane direction of the buffer die 110 and/or parallel to an upper surface 110S of the buffer die 110. The 2H-memory die 112 has a second width W2 in the horizontal direction. The second width W2 is larger than the first width W1 (e.g., the first width W1 is smaller than the second width W2). A 3H-memory die 113 has a third width W3 in the horizontal direction. The third width W3 is larger than the second width W2 (e.g., the second width W2 is smaller than the third width W3). The 4H-memory die 114 to the 12H-memory die 122 have a fourth width W4 in the horizontal direction. The fourth width W4 is larger than the third width W3. In some example embodiments, the first width W1 may be about 1.2% smaller than the fourth width W4. In some example embodiments, the second width W2 may be about 0.8% smaller than the fourth width W4. In an example, the third width W3 may be about 0.4% smaller than the fourth width W4. In some example embodiments, the first width W1, the second width W2, the third width W3, and the fourth width W4 may increase sequentially. In some example embodiments, the first width W1, the second width W2, the third width W3, and the fourth width W4 may sequentially increase at a constant rate.

In a test where the sizes of the bottom three 1H-memory die 111, 2H-memory die 112, and 3H-memory die 113 in the 12H-memory stack 210 were each reduced by about 1.2%, 0.8%, and 0.4% respectively compared to the fourth width W4 of the 4H-memory die 114 to the 12H-memory die 122, the stress acting on the buffer die 110 decreased by about 15%.

Through this, it can be seen that, according to the HBM 100 according to the present inventive concepts, it is possible to alleviate the stress concentration generated at the corner at the end of the interface formed by contact between the buffer die 110 and the 1H-memory die 111.

The molding material 190 is disposed on the buffer die 110, and molds the 12H-memory stack 210. The molding material 190 serves to protect and insulate the 12H-memory stack 210. In some example embodiments, the molding material 190 may be an epoxy molding compound (EMC).

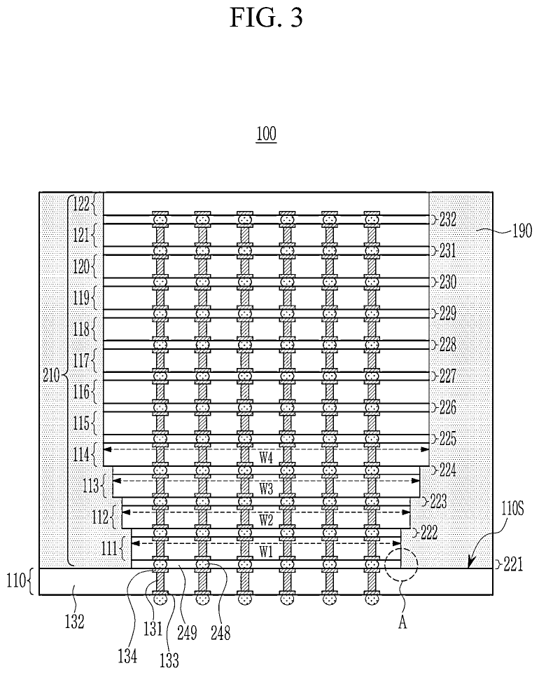

FIG. 3 is a cross-sectional view of the HBM 100 according to some example embodiments.

Referring to FIG. 3, the buffer die 110 and the 1H-memory die 111 to the 12H-memory die 122 of the 12H-memory stack 210 are connected to each other by the first interconnection structure 221 to the twelfth interconnection structure 232. Each of the first to twelfth interconnection structures 221 to 232 includes one or more connection members 248 and insulating members 249. In some example embodiments, the connection member 248 may include micro bumps. The insulating member 249 is disposed between the buffer die 110 and the 1H-memory die 111 to 12H-memory die 122 of the 12H-memory stack 210 and surrounds the connection members 248. The insulating member 249 relieves stress between the buffer die 110 and the 1H-memory die 111 to the 12H-memory die 122 of the 12H-memory stack 210. In some example embodiments, the insulating member 249 may include a non-conductive film (NCF).

The buffer die 110 and the 1H-memory die 111 to the 11H-memory die 121 each include a memory channel (not shown), first connection pads 133, through silicon vias 131, and second connection pads 134. The 12H-memory die 122 includes a memory channel (not shown), and the first connection pads 133.

The first connection pad 133 is disposed between the connection member 248 and the through silicon via 131. The first connection pad 133 electrically connects the through silicon via 131 to the connection member 248. The through silicon via 131 is disposed between the first connection pad 133 and the second connection pad 134. The through silicon via 131 electrically connects the second connection pad 134 to the first connection pad 133. The second connection pad 134 is disposed between the through silicon via 131 and the connection member 248. The second connection pad 134 electrically connects the connection member 248 to the through silicon via 131.

In FIG. 3, other configurations other than the first to twelfth interconnection structures 221 to 232 are the same as those shown in FIG. 1. Therefore, the contents described in FIG. 1 may be equally applied to other configurations other than the first to twelfth interconnection structures 221 to 232 in FIG. 3.

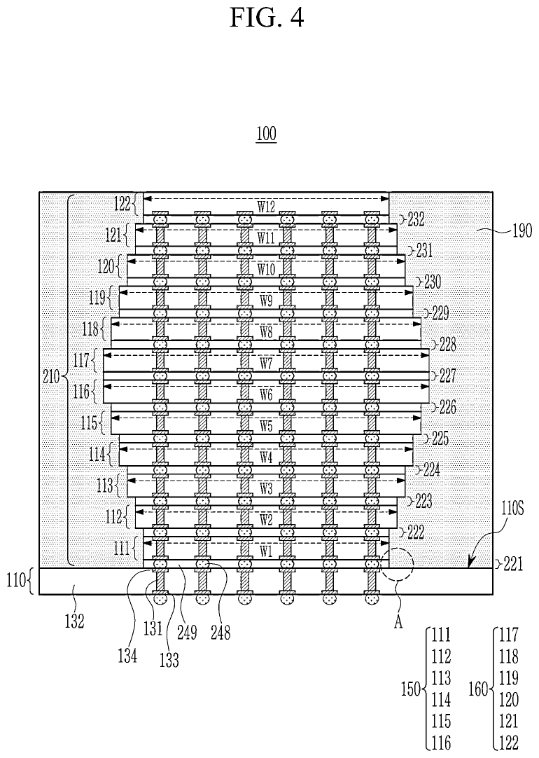

FIG. 4 is a cross-sectional view of the HBM 100 according to some example embodiments.

Referring to FIG. 4, the HBM 100 includes the buffer die 110, the 12H-memory stack 210 including the 1H-memory die 111 to the 12H-memory die 122, and the molding material 190. The 12H-memory stack 210 refers to a memory stack in which 12 memory dies are stacked. The memory dies arranged from the bottom to the top of the 12H-memory stack 210 are sequentially defined as the 1H-memory die 111 to the 12H-memory die 122.

The 12H-memory stack 210 includes a first sub-memory stack 150 and a second sub-memory stack 160. The first sub-memory stack 150 includes the 1H-memory die 111 to the 6H-memory die 116 (also referred to herein as a plurality of first memory dies of the first sub-memory stack 150). The first sub-memory stack 150 has a profile in which the horizontal width of each memory die (e.g., each memory die of the plurality of first memory dies) increases from the 1H-memory die 111 (which may be referred to a lower first memory die that is closest to the buffer die 110 among the plurality of first memory dies) to the 6H-memory die 116 (which may be referred to as an upper first memory die). The second sub-memory stack 160 includes a 7H-memory die 117 to the 12H-memory die 122 (also referred to herein as a plurality of second memory dies of the second sub-memory stack 160). The second sub-memory stack 160 has a profile in which the horizontal width of each memory die (e.g., each memory die of the plurality of second memory dies) decreases from the 7H-memory die 117 (which may be referred to a lower second memory die that is closest to the buffer die 110 among the plurality of second memory dies) to the 12H-memory die 122 (which may be referred to as an upper second memory die). In some example embodiments, the first sub-memory stack 150 and the second sub-memory stack 160 may each have a stepped side profile.

Thus, by adjusting the horizontal width of the 1H-memory die 111 to the 6H-memory die 116 of the first sub-memory stack 150, the corners at the ends of the interface formed by the buffer die 110 and the 12H-memory stack 210 may have a fillet or round shape (e.g., a fillet or round shape in a horizontal plane extending parallel to an in-plane direction of the buffer die 110, for example a horizontal plane that extends parallel to an upper surface 110S of the buffer die 110) without any additional machining. Thus, it is possible to alleviate (e.g., reduce or minimize) the stress concentrated at the corner. Restated, the HBM 100 may be configured to have reduced stress concentration at the corner A at the end of the interface formed by the contact of the buffer die 110 and the memory stack 210 at the bottom memory die thereof (e.g., adjacent to the buffer die 110, closest to the buffer die 110 among the 1H-memory die 111 to the 12H-memory die 122 included in the memory stack 210, etc.), and thus improved performance and/or reliability due to reduced likelihood of stress concentration-induced defects, based on the first sub-memory stack 150 having a profile in which a horizontal width of each memory die of the plurality of first memory dies (e.g., widths W1 to W6) increases from a lower first memory die of the plurality of first memory dies (e.g., the 1H-memory die 111) to an upper first memory die of the plurality of first memory dies (e.g., the 6H-memory die 116).

In addition, it is possible to improve warpage characteristics of the HBM 100 by adjusting the horizontal width of the 7H-memory die 117 to the 12H-memory die 122 of the second sub-memory stack 160. Restated, the HBM 100 may be configured to have reduced warpage, and thus improved performance and/or reliability due to reduced likelihood of warpage-induced defects based on the second sub-memory stack 160 having a profile in which a horizontal width of each memory die of the plurality of second memory dies (e.g., widths W7 to W12) decreases from a lower second memory die of the plurality of second memory dies (e.g., the 7H-memory die 117) to an upper second memory die of the plurality of second memory dies (e.g., the 12H-memory die 122).

The 1H-memory die 111 has the first width W1 in the horizontal direction (where the horizontal direction may extend parallel to an in-plane direction of the buffer die 110 and/or parallel to an upper surface 110S of the buffer die 110). The 2H-memory die 112 has the second width W2 in the horizontal direction. The second width W2 is larger than the first width W1. The 3H-memory die 113 has the third width W3 in the horizontal direction. The third width W3 is larger than the second width W2. The 4H-memory die 114 has the fourth width W4 in the horizontal direction. The fourth width W4 is larger than the third width W3. The 5H-memory die 115 has a fifth width W5 in the horizontal direction. The fifth width W5 is larger than the fourth width W4. The 6H-memory die 116 has a sixth width W6 in the horizontal direction. The sixth width W6 is larger than the fifth width W5. In some example embodiments, the first to sixth widths W1 to W6 (e.g., the magnitudes thereof in the horizontal direction) may increase sequentially (e.g., increase sequentially with increasing distance from the upper surface 110S of the buffer die 110 in a vertical direction perpendicular to the in-plane direction of the buffer die 110 and/or perpendicular to the upper surface 110S of the buffer die 110). In some example embodiments, the first to sixth widths W1 to W6 may sequentially increase at a constant rate as a function of distance from the upper surface 110S of the buffer die 110 in a vertical direction perpendicular to the in-plane direction of the buffer die 110 and/or perpendicular to the upper surface 110S of the buffer die 110.

The 7H-memory die 117 has a seventh width W7 in the horizontal direction. The seventh width W7 is the same as the sixth width W6. An 8H-memory die 118 has an eighth width W8 in the horizontal direction. The eighth width W8 is smaller than the seventh width W7. A 9H-memory die 119 has a ninth width W9 in the horizontal direction. The ninth width W9 is smaller than the eighth width W8. The 10H-memory die 120 has a tenth width W10 in the horizontal direction. The tenth width W10 is smaller than the ninth width W9. An 11H-memory die 121 has an eleventh width W11 in the horizontal direction. The eleventh width W11 is smaller than the tenth width W10. The 12H-memory die 122 has a twelfth width W12 in the horizontal direction. The twelfth width W12 is smaller than the eleventh width W11. In some example embodiments, the seventh to twelfth widths W7 to W12 may sequentially decrease (e.g., decrease sequentially with increasing distance from the upper surface 110S of the buffer die 110 in a vertical direction perpendicular to the in-plane direction of the buffer die 110 and/or perpendicular to the upper surface 110S of the buffer die 110). In some example embodiments, the seventh to twelfth widths W7 to W12 may sequentially decrease at a constant rate as a function of distance from the upper surface 110S of the buffer die 110 in a vertical direction perpendicular to the in-plane direction of the buffer die 110 and/or perpendicular to the upper surface 110S of the buffer die 110.

According to the present inventive concepts, the first sub-memory stack 150 and the second sub-memory stack 160 are shown and described as including the same number (quantity) of memory dies, but the present inventive concepts are not limited thereto. In consideration of the purpose of the present inventive concepts to prevent stress from occurring at the corner and the warpage characteristics, the 1H-memory die 111 to the 12H-memory die 122 may be randomly divided to configure the first sub-memory stack 150 and the second sub-memory stack 160, including various combinations of memory dies.

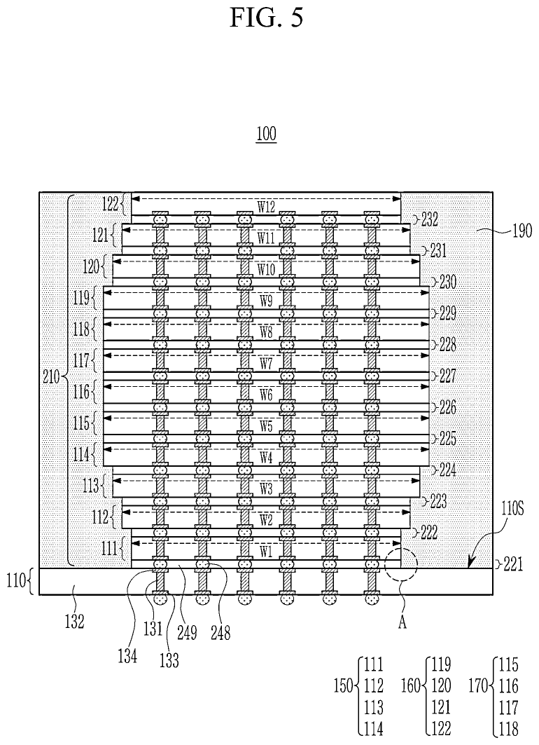

FIG. 5 is a cross-sectional view of the HBM 100 according to some example embodiments.

Referring to FIG. 5, the HBM 100 includes the buffer die 110, the 12H-memory stack 210 including the 1H-memory die 111 to the 12H-memory die 122, and the molding material 190. The 12H-memory stack 210 refers to a memory stack in which 12 memory dies are stacked. The memory dies arranged from the bottom to the top of the 12H-memory stack 210 are sequentially defined as the 1H-memory die 111 to the 12H-memory die 122.

The 12H-memory stack 210 includes the first sub-memory stack 150, the second sub-memory stack 160, and a third sub-memory stack 170. The first sub-memory stack 150 includes the 1H-memory die 111 to the 4H-memory die 114 (also referred to as a plurality of first memory dies). The first sub-memory stack 150 has a profile in which the horizontal width of each memory die increases from the 1H-memory die 111 to the 4H-memory die 114. The second sub-memory stack 160 includes the 9H-memory die 119 to the 12H-memory die 122 (also referred to as a plurality of second memory dies). The second sub-memory stack 160 has a profile in which the horizontal width of each memory die decreases from the 9H-memory die 119 to the 12H-memory die 122. In some example embodiments, the first sub-memory stack 150 and the second sub-memory stack 160 may each have a stepped side profile.

The third sub-memory stack 170 includes the 5H-memory die 115 to the 8H-memory die 118 (also referred to as a plurality of third memory dies). The third sub-memory stack 170 has a profile in which the horizontal width of each memory die is constant from the 5H-memory die 115 (also referred to as a lower third memory die that is closest to the buffer die 110 among the plurality of third memory dies) to the 8H-memory die 118 (also referred to as an upper third memory die).

Thus, by adjusting the horizontal width of the 1H-memory die 111 to the 4H-memory die 114 of the first sub-memory stack 150, the corners at the ends of the interface formed by the buffer die 110 and the 12H-memory stack 210 may have a fillet or round shape (e.g., a fillet or round shape in a horizontal plane extending parallel to an in-plane direction of the buffer die 110, for example a horizontal plane that extends parallel to an upper surface 110S of the buffer die 110) without any additional machining. Thus, it is possible to alleviate the stress concentrated at the corner. Restated, the HBM 100 may be configured to have reduced stress concentration at the corner A at the end of the interface formed by the contact of the buffer die 110 and the memory stack 210 at the bottom memory die thereof (e.g., adjacent to the buffer die 110, closest to the buffer die 110 among the 1H-memory die 111 to the 12H-memory die 122 included in the memory stack 210, etc.), and thus improved performance and/or reliability due to reduced likelihood of stress concentration-induced defects, based on the first sub-memory stack 150 having a profile in which a horizontal width of each memory die of the plurality of first memory dies (e.g., widths W1 to W4) increases from a lower first memory die of the plurality of first memory dies (e.g., the 1H-memory die 111) to an upper first memory die of the plurality of first memory dies (e.g., the 4H-memory die 114).

In addition, it is possible to improve warpage characteristics of the HBM 100 by adjusting the horizontal width of the 9H-memory die 119 to the 12H-memory die 122 of the second sub-memory stack 160, and maintaining the horizontal width of the 5H-memory die 115 to the 8H-memory die 118 of the third sub-memory stack 170 constantly. Restated, the HBM 100 may be configured to have reduced warpage, and thus improved performance and/or reliability due to reduced likelihood of warpage-induced defects based on the second sub-memory stack 160 having a profile in which a horizontal width of each memory die of the plurality of second memory dies (e.g., widths W9 to W12) decreases from a lower second memory die of the plurality of second memory dies (e.g., the 9H-memory die 119) to an upper second memory die of the plurality of second memory dies (e.g., the 12H-memory die 122).

The 1H-memory die 111 has the first width W1 in the horizontal direction. The 2H-memory die 112 has the second width W2 in the horizontal direction. The second width W2 is larger than the first width W1. The 3H-memory die 113 has the third width W3 in the horizontal direction.

The third width W3 is larger than the second width W2. The 4H-memory die 114 has the fourth width W4 in the horizontal direction. The fourth width W4 is larger than the third width W3. In some example embodiments, the first to fourth widths W1 to W4 may increase sequentially (e.g., increase sequentially with increasing distance from the upper surface 110S of the buffer die 110 in a vertical direction perpendicular to the in-plane direction of the buffer die 110 and/or perpendicular to the upper surface 110S of the buffer die 110). In some example embodiments, the first to fourth widths W1 to W4 may sequentially increase at a constant rate as a function of distance from the upper surface 110S of the buffer die 110 in a vertical direction perpendicular to the in-plane direction of the buffer die 110 and/or perpendicular to the upper surface 110S of the buffer die 110.

The 5H-memory die 115 has the fifth width W5 in the horizontal direction. The fifth width W5 is the same as the fourth width W4. The 6H-memory die 116 has the sixth width W6 in the horizontal direction. The sixth width W6 is the same as the fifth width W5. The 7H-memory die 117 has the seventh width W7 in the horizontal direction. The seventh width W7 is the same as the sixth width W6. The 8H-memory die 118 has the eighth width W8 in the horizontal direction. The eighth width W8 is the same as the seventh width W7.

The 9H-memory die 119 has the ninth width W9 in the horizontal direction. The ninth width W9 is the same as the eighth width W8. The 10H-memory die 120 has the tenth width W10 in the horizontal direction. The tenth width W10 is smaller than the ninth width W9. The 11H-memory die 121 has the eleventh width W11 in the horizontal direction. The eleventh width W11 is smaller than the tenth width W10. The 12H-memory die 122 has the twelfth width W12 in the horizontal direction. The twelfth width W12 is smaller than the eleventh width W11. In some example embodiments, the ninth to twelfth widths W9 to W12 may sequentially decrease (e.g., decrease sequentially with increasing distance from the upper surface 110S of the buffer die 110 in a vertical direction perpendicular to the in-plane direction of the buffer die 110 and/or perpendicular to the upper surface 110S of the buffer die 110). In some example embodiments, the ninth to twelfth widths W9 to W12 may sequentially decrease at a constant rate as a function of distance from the upper surface 110S of the buffer die 110 in a vertical direction perpendicular to the in-plane direction of the buffer die 110 and/or perpendicular to the upper surface 110S of the buffer die 110.

According to the present inventive concepts, the first sub-memory stack 150, the second sub-memory stack 160 and the third sub-memory stack 170 are shown and described as including the same number of memory dies, but the present inventive concepts are not limited thereto. In consideration of the purpose of the present inventive concepts to prevent stress from occurring at the corner and the warpage characteristics, or to reduce or minimize such stress occurrence, the 1H-memory die 111 to the 12H-memory die 122 may be randomly divided to configure the first sub-memory stack 150, the second sub-memory stack 160 and the third sub-memory stack 170 including various combinations of memory dies.

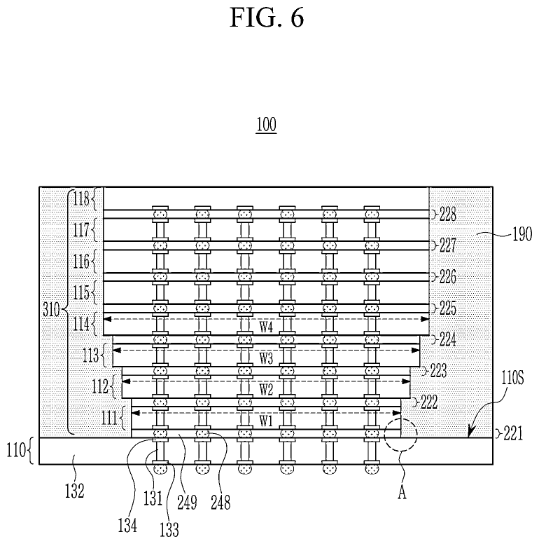

FIG. 6 is a cross-sectional view of the HBM 100 according to some example embodiments.

Referring to FIG. 6, the HBM 100 includes the buffer die 110, an 8H-memory stack 310 including the 1H-memory die 111 to the 8H-memory die 118, and the molding material 190. The 8H-memory stack 310 refers to a memory stack in which eight memory dies are stacked. The memory dies arranged from the bottom to the top of the 8H-memory stack 310 are sequentially defined as the 1H-memory die 111 to the 8H-memory die 118.

The 8H-memory stack 310 has a profile in which the horizontal width of each memory die increases from the 1H-memory die 111 to the 4H-memory die 114, and the horizontal width of the 4H-memory die 114 to the 8H-memory die 118 is constant. In some example embodiments, the 1H-memory die 111 to the 4H-memory die 114 of the 8H-memory stack 310 may have a stepped side profile. Thus, by adjusting the horizontal width of the 1H-memory die 111 to the 4H-memory die 114, the corners at the ends of the interface formed by the buffer die 110 and the 8H-memory stack 310 may have a fillet or round shape (e.g., a fillet or round shape in a horizontal plane extending parallel to an in-plane direction of the buffer die 110, for example a horizontal plane that extends parallel to an upper surface 110S of the buffer die 110) without any additional machining. Thus, it is possible to alleviate the stress concentrated at the corner. Restated, the HBM 100 may be configured to have reduced stress concentration at the corner A at the end of the interface formed by the contact of the buffer die 110 and the 8H-memory stack 310 at the bottom memory die thereof (e.g., adjacent to the buffer die 110, closest to the buffer die 110 among the 1H-memory die 111 to the 8H-memory die 118 included in the 8H-memory stack 310, etc.), and thus improved performance and/or reliability due to reduced likelihood of stress concentration-induced defects, based on the 8H-memory stack 310 having a profile in which a horizontal width of the 1H-memory die 111 to the 4H-memory die 114 of the 8H-memory stack 310 (e.g., widths W1 to W4) increases from the 1H-memory die 111 to the 4H-memory die 114.

The 1H-memory die 111 has the first width W1 in the horizontal direction. The 2H-memory die 112 has the second width W2 in the horizontal direction. The second width W2 is larger than the first width W1. The 3H-memory die 113 has the third width W3 in the horizontal direction. The third width W3 is larger than the second width W2. The 4H-memory die 114 to the 8H-memory die 118 have the fourth width W4 in the horizontal direction. The fourth width W4 is larger than the third width W3. In some example embodiments, the first width W1 may be about 1.2% smaller than the fourth width W4. In some example embodiments, the second width W2 may be about 0.8% smaller than the fourth width W4. In an example, the third width W3 may be about 0.4% smaller than the fourth width W4. In some example embodiments, the first width W1, the second width W2, the third width W3 and the fourth width W4 may increase sequentially (e.g., increase sequentially with increasing distance from the upper surface 110S of the buffer die 110 in a vertical direction perpendicular to the in-plane direction of the buffer die 110 and/or perpendicular to the upper surface 110S of the buffer die 110). In some example embodiments, the first width W1, the second width W2, the third width W3 and the fourth width W4 may sequentially increase at a constant rate as a function of distance from the upper surface 110S of the buffer die 110 in a vertical direction perpendicular to the in-plane direction of the buffer die 110 and/or perpendicular to the upper surface 110S of the buffer die 110.

According to the present inventive concepts, although it is shown and described that the 8H-memory stack 310 has a profile in which the horizontal width of each memory die increases from the 1H-memory die 111 to the 4H-memory die 114, and the horizontal width of each memory die from the 4H-memory die 114 to the 8H-memory die 118 is constant, but the example embodiments of the HBM 100 described with respect to FIGS. 4 and 5 may be equally applicable to the HBM 100 of FIG. 6.

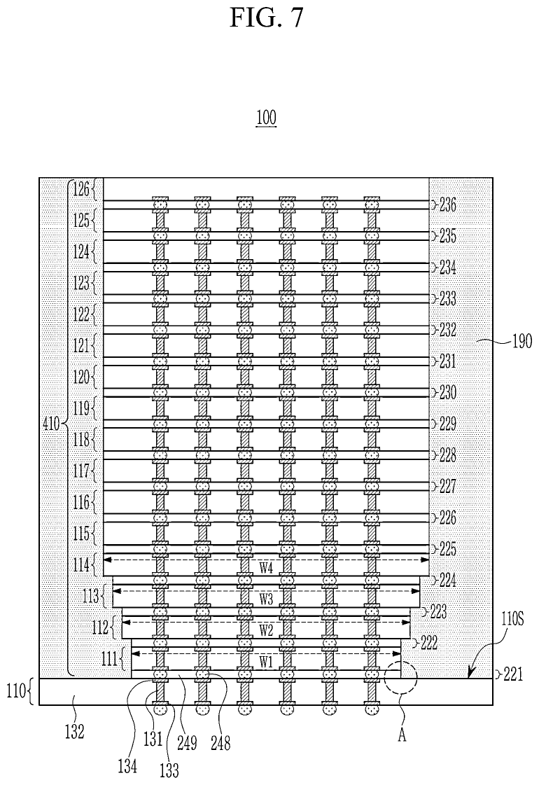

FIG. 7 is a cross-sectional view of the HBM 100 according to some example embodiments.

Referring to FIG. 7, the HBM 100 includes the buffer die 110, an 16H-memory stack 410 including the 1H-memory die 111 to a 16H-memory die 126, and the molding material 190. The 16H-memory stack 410 refers to a memory stack in which sixteen memory dies are stacked. The memory dies arranged from the bottom to the top of the 16H-memory stack 410 are sequentially defined as the 1H-memory die 111 to the 16H-memory die 126.

The 16H-memory stack 410 has a profile in which the horizontal width of each memory die increases from the 1H-memory die 111 to the 4H-memory die 114, and the horizontal width of the 4H-memory die 114 to the 16H-memory die 126 is constant. In some example embodiments, the 1H-memory die 111 to the 4H-memory die 114 of the 16H-memory stack 410 may have a stepped side profile. Thus, by adjusting the horizontal width of the 1H-memory die 111 to the 4H-memory die 114, the corners at the ends of the interface formed by the buffer die 110 and the 16H-memory stack 410 may have a fillet or round shape (e.g., a fillet or round shape in a horizontal plane extending parallel to an in-plane direction of the buffer die 110, for example a horizontal plane that extends parallel to an upper surface 110S of the buffer die 110) without any additional machining. Thus, it is possible to alleviate the stress concentrated at the corner. Restated, the HBM 100 may be configured to have reduced stress concentration at the corner A at the end of the interface formed by the contact of the buffer die 110 and the memory stack 410 at the bottom memory die thereof (e.g., adjacent to the buffer die 110, closest to the buffer die 110 among the 1H-memory die 111 to the 16H-memory die 126 included in the memory stack 410, etc.), and thus improved performance and/or reliability due to reduced likelihood of stress concentration-induced defects, based on the memory stack 410 having a profile in which a horizontal width of the 1H-memory die 111 to the 4H-memory die 114 of the 16H-memory stack 410 (e.g., widths W1 to W4) increases from the 1H-memory die 111 to the 4H-memory die 114.

The 1H-memory die 111 has the first width W1 in the horizontal direction. The 2H-memory die 112 has the second width W2 in the horizontal direction. The second width W2 is larger than the first width W1. The 3H-memory die 113 has the third width W3 in the horizontal direction. The third width W3 is larger than the second width W2. The 4H-memory die 114 to the 16H-memory die 126 have the fourth width W4 in the horizontal direction. The fourth width W4 is larger than the third width W3. In some example embodiments, the first width W1 may be about 1.2% smaller than the fourth width W4. In some example embodiments, the second width W2 may be about 0.8% smaller than the fourth width W4. In an example, the third width W3 may be about 0.4% smaller than the fourth width W4. In some example embodiments, the first width W1, the second width W2, the third width W3 and the fourth width W4 may increase sequentially (e.g., increase sequentially with increasing distance from the upper surface 110S of the buffer die 110 in a vertical direction perpendicular to the in-plane direction of the buffer die 110 and/or perpendicular to the upper surface 110S of the buffer die 110). In some example embodiments, the first width W1, the second width W2, the third width W3 and the fourth width W4 may sequentially increase at a constant rate as a function of distance from the upper surface 110S of the buffer die 110 in a vertical direction perpendicular to the in-plane direction of the buffer die 110 and/or perpendicular to the upper surface 110S of the buffer die 110.

According to the present inventive concepts, although it is shown and described that the 16H-memory stack 410 has a profile in which the horizontal width of each memory die increases from the 1H-memory die 111 to the 4H-memory die 114, and the horizontal width of each memory die from the 4H-memory die 114 to the 16H-memory die 126 is constant, but the example embodiments of the HBM 100 described with respect to FIGS. 4 and 5 may be equally applicable to the HBM 100 of FIG. 7.

While the inventive concepts have been described in connection with what is presently considered to be practical example embodiments, it is to be understood that the inventive concepts are not limited to such example embodiments, but, on the contrary, the inventive concepts are intended to cover various modifications and equivalent arrangements included within the spirit and scope of the appended claims.

What is claimed is:

1. A high bandwidth memory, comprising:
a base die; and
a memory stack on the base die, wherein the memory stack includes a plurality of memory dies,
wherein the memory stack includes
a first memory die closest to the base die among the plurality of memory dies, the first memory die having a first width in a horizontal direction, the horizontal direction extending parallel to an in-plane direction of the base die, and
a second memory die on the first memory die, the second memory die having a second width in the horizontal direction,
wherein the first width is smaller than the second width.

2. The high bandwidth memory of claim 1, wherein:
the memory stack further comprises a third memory die on the second memory die, the third memory die having a third width in the horizontal direction, and
the second width is smaller than the third width.

3. The high bandwidth memory of claim 2, wherein:
the memory stack further comprises fourth to eighth memory dies that are sequentially stacked.

4. The high bandwidth memory of claim 3, wherein:
the memory stack further comprises ninth to twelfth memory dies that are sequentially stacked.

5. The high bandwidth memory of claim 4, wherein:
the fourth to twelfth memory dies each have a fourth width in the horizontal direction.

6. The high bandwidth memory of claim 5, wherein:
the first width is 1.2% smaller than the fourth width.

7. The high bandwidth memory of claim 5, wherein:
the second width is 0.8% smaller than the fourth width.

8. The high bandwidth memory of claim 5, wherein:
the third width is 0.4% smaller than the fourth width.

9. The high bandwidth memory of claim 4, wherein:
the memory stack further includes thirteenth to sixteenth memory dies that are sequentially stacked.

10. A high bandwidth memory, comprising:
a base die; and
a memory stack on the base die, wherein the memory stack includes a first sub-memory stack and a second sub-memory stack, the first sub-memory stack includes a plurality of first memory dies, and the second sub-memory stack each includes a plurality of second memory dies,
wherein the first sub-memory stack has a profile in which a horizontal width in a horizontal direction of each memory die of the plurality of first memory dies increases from a lower first memory die of the plurality of first memory dies to an upper first memory die of the plurality of first memory dies, the lower first memory die closest to the base die among the plurality of first memory dies, the horizontal direction extending parallel to an in-plane direction of the base die, and
wherein the second sub-memory stack has a profile in which a horizontal width of each memory die of the plurality of second memory dies decreases from a lower second memory die of the plurality of second memory dies to an upper second memory die of the plurality of second memory dies, the lower second memory die closest to the base die among the plurality of second memory dies.

11. The high bandwidth memory of claim 10, further comprising:
a third sub-memory stack between the first sub-memory stack and the second sub-memory stack,
wherein the third sub-memory stack includes a plurality of third memory dies.

12. The high bandwidth memory of claim 11, wherein:
the third sub-memory stack has a profile in which a horizontal width of each memory die of the plurality of third memory dies is constant from a lower third memory die of the plurality of third memory dies to an upper third memory die of the plurality of third memory dies, the lower third memory die closest to the base die among the plurality of third memory dies.

13. The high bandwidth memory of claim 10, wherein:
the first sub-memory stack has a profile in which the horizontal width of each memory die of the first plurality of memory dies increases at a constant rate from the lower first memory die to the upper first memory die.

14. The high bandwidth memory of claim 10, wherein:
the second sub-memory stack has a profile in which the horizontal width of each memory die of the plurality of second memory dies decreases at a constant rate from the lower second memory die to the upper second memory die.

15. A high bandwidth memory, comprising:
a base die;
a memory stack on the base die, the memory stack including
a plurality of memory dies, and
a plurality of interconnection structures; and
a molding material molding the memory stack on the base die,
wherein the plurality of memory dies includes
a first memory die closest to the base die among the plurality of memory dies, the first memory die having a first width in a horizontal direction, the horizontal direction extending parallel to an in-plane direction of the base die, and
a second memory die on the first memory die, the second memory die having a second width in the horizontal direction, the second width greater than the first width, the plurality of interconnection structures includes
a first interconnection structure connecting the base die and the first memory die, and
a second interconnection structure connecting the first memory die and the second memory die.

16. The high bandwidth memory of claim 15, wherein:
the first memory die and the second memory die each include a plurality of through silicon vias.

17. The high bandwidth memory of claim 15, wherein:
the base die is a buffer die.

18. The high bandwidth memory of claim 15, wherein:
the plurality of memory dies are DRAM.

19. The high bandwidth memory of claim 15, wherein:
each of the plurality of interconnection structures comprises:
a plurality of micro bumps; and
non-conductive film (NCF) insulating the plurality of micro bumps.

20. The high bandwidth memory of claim 15, wherein:
each of the plurality of interconnection structures comprises
a plurality of first bonding pads;
a first silicon insulating layer insulating the plurality of first bonding pads;
a plurality of second bonding pads located on the plurality of first bonding pads, the plurality of second bonding pads directly bonded to the plurality of first bonding pads; and
a second silicon insulating layer located on the first silicon insulating layer and directly bonded to the first silicon insulating layer.
